(19) United States
(12) Patent Application Publication
(10) Pub. No.: US 2012/0320538 A1
(43) Pub. Date: Dec. 20, 2012

(54) SERIAL ADVANCED TECHNOLOGY ATTACHMENT DIMM

(75) Inventors: KANG WU, Shenzhen City (CN); GUO-YI CHEN, Shenzhen City (CN); WEN-SEN HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/173,209

(22) Filed: Jun. 30, 2011

(30) Foreign Application Priority Data
Jun. 15, 2011 (CN) 201110160492.7

(51) Int. Cl. H05K 7/00

(52) U.S. Cl. 361/748

(57) ABSTRACT

A serial advanced technology attachment (SATA) DIMM includes a board body. A control chip and a power circuit are set on the board body. An edge connector is set on a side of the board body and inserted into a memory slot of a motherboard. The edge connector includes a number of power pins, a number of ground pins, and a number of signal pins. The power pins are connected to the power circuit. The signal pins are connected to the control chip.

### BACKGROUND

1. Technical Field

The present disclosure relates to a serial advanced technology attachment (SATA) DIMM.

2. Description of Related Art

Solid state drives (SSD) store data on chips instead of magnetic or optical discs as traditional drives. One type of SSD has the form factor of a dual-in-line memory module (DIMM) module and is called a serial advanced technology attachment (SATA) DIMM. As such, the SATADIMM can be inserted into a memory slot of a motherboard, to receive a voltage from the motherboard through the memory slot. However, hard disk drive (HDD) signals need to be transmitted between the SATADIMM and the motherboard through a SATA connector set on the SATADIMM connected to a SATA connector of the motherboard. Moreover, the SATA connector set on the SATADIMM may occupy a lot of space. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of a serial advanced technology attachment (SATA) DIMM in accordance with an exemplary embodiment of the present disclosure.

FIG. 2 is a schematic diagram of the SATADIMM of FIG. 1 connected to a motherboard.

### DETAILED DESCRIPTION

The disclosure, including the drawings, is illustrated by way of example and not by limitation. References to “an” or “one” embodiment in this disclosure are not necessarily to the same embodiment, and such references mean at least one.

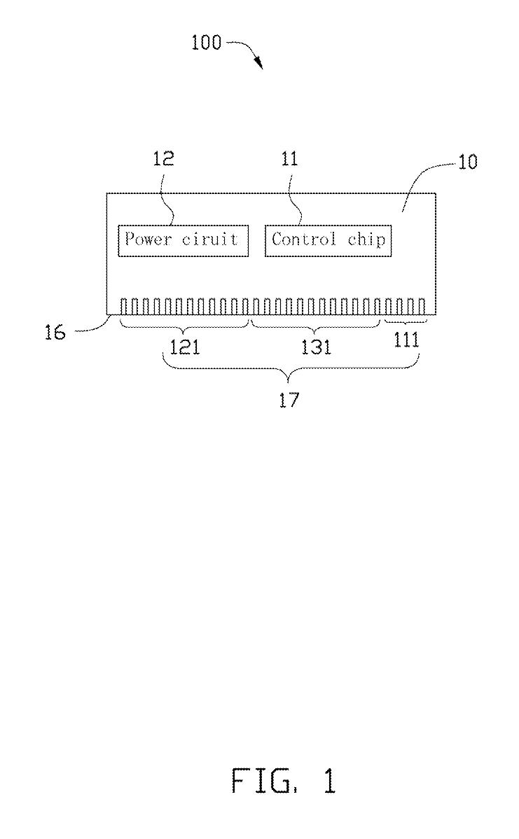

Referring to FIG. 1, a serial advanced technology attachment (SATA) DIMM 100 in accordance with an exemplary embodiment includes a board body 10. The board body 10 is substantially a rectangle-shape. A control chip 11 and a power circuit 12 are arranged on the board body 10. An edge connector 17 is set on a side 16 of the board body 10. The edge connector 17 includes a plurality of signal pins 111, a plurality of power pins 121, and a plurality of ground pins 131. The signal pins 111 include a pair of signal input pins and a pair of signal output pins. The power pins 121 are connected to the power circuit 12 through conductive lines of the board body 10. The signal pins 111 are connected to the control chip 11 through conductive lines of the board body 10. The ground pins 131 are connected to a ground layer (not shown) of the SATADIMM 100, to be grounded.

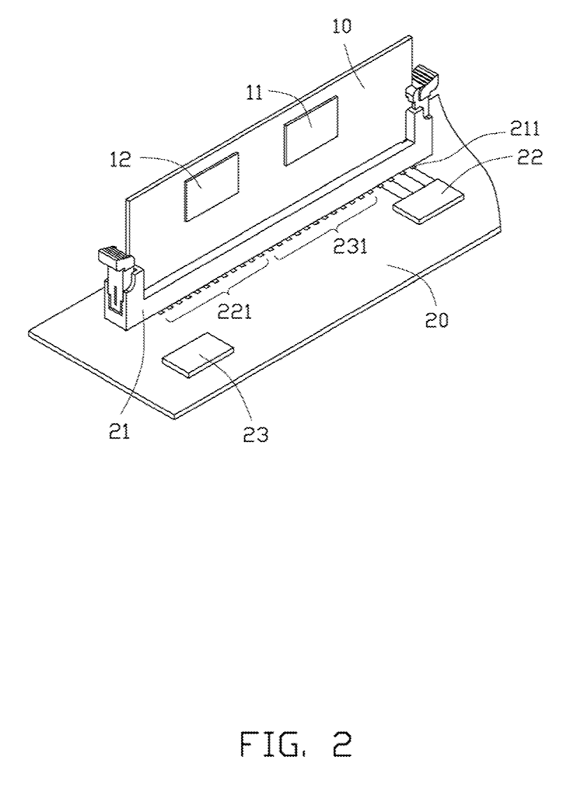

Referring to FIG. 2, a hard disk drive (HDD) controller 22 and a memory slot 21 are arranged in a motherboard 20. The memory slot 21 may be a double data rate type three (DDR3) slots or a double data rate type two (DDR2) slots. The memory slot 21 includes a plurality of power pins 221 corresponding to the power pins 121 of the SATADIMM 100, a plurality of ground pins 231 corresponding to the ground pins 131 of the SATADIMM 100, and a plurality of idle pins. Four idle pins 211 of the memory slot 21 are respectively connected to the HDD controller 22 through conductive lines of the motherboard 20, and corresponding to the signal pins 111 of the SATADIMM 100. Namely, when the edge connector 17 of the SATADIMM 100 is inserted into the memory slot 21, the signal pins 111 of the SATADIMM 100 are electrically connected to the idle pins 211 of the memory slot 21 of the motherboard 20, the power pins 121 of the SATADIMM 100 are electrically connected to the power pins 221 of the memory slot 21, and the ground pins 131 of the SATADIMM 100 are electrically connected to the ground pins 231 of the memory slot 21. The power pins 221 of the memory slot 21 are connected to a power connector 23 of the motherboard 20 through conductive lines of the motherboard 20, to receive a voltage. The ground pins 231 of the memory slot 21 are connected to a ground layer (not shown) of the motherboard 20, to be grounded.

In use, the SATADIMM 100 is inserted into the memory slot 21 of the motherboard 20 through the edge connector 17. When the motherboard 20 is powered on, the motherboard 20 outputs a voltage to the power circuit 12 of the SATADIMM 100 through the power pins 221 of the memory slot 21 and the power pins 121 of the SATADIMM 100, to provide the voltage to the control chip 11 and other components (not shown) of the SATADIMM 100. At the same time, the HDD controller 22 of the motherboard 20 outputs an HDD signal, such as a serial advanced technology attachment (SATA) signal to the control chip 11 of the SATADIMM 100 through the idle pins 211 of the memory slot 21 and the signal pins 111 of the SATADIMM 100, to make the control chip 11 control the SATADIMM 100 to communicate with the motherboard 20. Therefore, the HDD signals can be transmitted between the SATADIMM 100 and the motherboard 20 for communication through the idle pins 211 of the memory slot 21 and the signal pins 111 set on the SATADIMM 100, to replace the common interface connector set on the SATADIMM 100, to further save more space on the SATADIMM 100.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A serial advanced technology attachment (SATA) dual-in-line memory module (DIMM) comprising:
a board body;
a control chip set on the board body;
a power circuit set on the board body; and
an edge connector set on a side of the board body, the edge connector comprising a plurality of power pins connected to the power circuit, a plurality of signal pins connected to the control chip, and a plurality of ground pins.

2. The SATADIMM of claim 1, wherein the plurality of signal pins comprises a pair of signal input pins and a pair of signal output pins.

3. A motherboard for supporting a serial advanced technology attachment (SATA) dual-in-line memory module (DIMM), the motherboard comprising:
a power connector;
a memory slot comprising a plurality of power pins electrically connected to the power connector, a plurality of ground pin which is grounded, and a plurality of idle pins; and
a hard disk drive controller electrically connected to the plurality of idle pins of the memory slot.

4. The motherboard of claim 3, wherein the plurality of idle pins comprises four idle pins.

5. The motherboard of claim 4, wherein the memory slot is a double data rate type three (DDR3) slot or a double data rate type two (DDR2) slot.

6. An assembly comprising:
a motherboard comprising a memory slot, a hard disk drive (HDD) controller, and a power connector, the memory slot comprising a plurality of power pins electrically connected to the power connector, a plurality of ground pins grounded, and a plurality of idle pins connected to the HDD controller; and
a serial advanced technology attachment (SATA) dual-in-line memory module (DIMM) comprising a board body, a control chip and a power circuit set on the board body, and an edge connector set on a side of the board body to be detachably engaged in the memory slot of the motherboard, the edge connector comprising a plurality of power pins connected to the power circuit, a plurality of ground pins, and a plurality of signal pins connected to the control chip;
wherein in response to the edge connector of the SATADIMM being engaged in the memory slot, the power pins of the SATADIMM are connected to the power pins of the memory slot, the ground pins of the SATADIMM are connected to the ground pins of the memory slot, and the signal pins of the SATADIMM are connected to the idle pins of the memory slot.

7. The assembly of claim 6, wherein the plurality of signal pins comprises a pair of signal input pins and a pair of signal output pins.
